(19) United States
(12) Patent Application Publication
(10) Pub. No.: US 2007/0072341 A1
(43) Pub. Date: Mar. 29, 2007

(54) Die package and method for making the same

(76) Inventors: Wei-Chang Tai, Kaohsiung (TW); Cheng-Yin Lee, Kaohsiung (TW)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/505,325

(22) Filed: Aug. 17, 2006

(30) Foreign Application Priority Data
Sep. 14, 2005 (TW) 094131694

(51) Int. Cl. H01L 21/78

(52) U.S. Cl. 438/107; 438/113; 438/613

(57) ABSTRACT

The present invention relates to a die package and method for making the same. The method of the invention comprises the steps of: (a) providing a plate, having a first surface and a second surface; (b) forming a plurality of first dice on the plate, the first dice having a first surface and a second surface; (c) forming a plurality of bumps on the first surface of the first dice; and (d) cutting the plate to form a plurality of die modules, each module comprising a plate unit, a first die and a plurality of bumps, the first die disposed on a first surface of the plate unit, whereby the bumps could be easily mounted on the single die.

### BACKGROUND OF THE INVENTION

1. Field of the Invention

The invention relates to a packaging method for a die, particularly to a die package and method for making the same.

2. Description of the Related Art

Referring to FIGS. 1A to 1C, they show a conventional method for making a die. Referring to FIG. 1A, firstly, a wafer 11 is provided. The wafer 11 is defined as a plurality of dice 111 (dashed lines) and has a first surface 112. Referring to FIG. 1B, a plurality of bumps 12 are formed on the first surface 112 of the wafer 11, wherein the bumps 12 are gold preferably. Referring to FIG. 1C, finally, the wafer 11 is cut to form a plurality of dice 111.

In the conventional method, firstly, the bumps 12 are mounted on the wafer 11, and then the wafer 11 is cut to form a plurality of dice 111. Therefore, it is difficult and time-consurning to mount bumps on a single die, so that the conventional method cannot satisfy the need for mounting bumps on a single die.

Consequently, there is an existing need for providing a die package and method for making the same to solve the above-mentioned problems.

### SUMMARY OF THE INVENTION

One objective of the present invention is to provide a die package and method for making the same so that the bumps can be mounted on the single die, and furthermore, the die can be used in a stacked package.

For the above objective, the method of the invention comprises the steps of: (a) providing a plate, having a first surface and a second surface; (b) forming a plurality of first dice on the plate, the first dice having a first surface and a second surface; (c) forming a plurality of bumps on the first surface of the first dice; and (d) cutting the plate to form a plurality of die modules, each module comprising a plate unit, a first die and a plurality of bumps, the first die disposed on a first surface of the plate unit.

Another objective of the present invention is to provide a package with a die module. The package comprises a die module and a substrate. The die module comprises a plate unit, a first die and a plurality of bumps. The plate unit has a first surface and a second surface. The first die is disposed on the first surface of the plate unit. The die has a first surface and a second surface. The bumps are disposed on the first surface of the first die. The substrate has a first surface and a second surface. The die module is disposed upside down on the first surface of the substrate, and the bumps electrically connect to the substrate directly.

### BRIEF DESCRIPTION OF THE DRAWINGS

FIGS. 1A to 1C show a conventional method for making a die;

FIGS. 2A to 2C show a method for mounting bumps on a die according to the present invention;

FIG. 2D shows a package with a die module according to the present invention; and

FIG. 2E shows a stacked package with a die module according to the present invention.

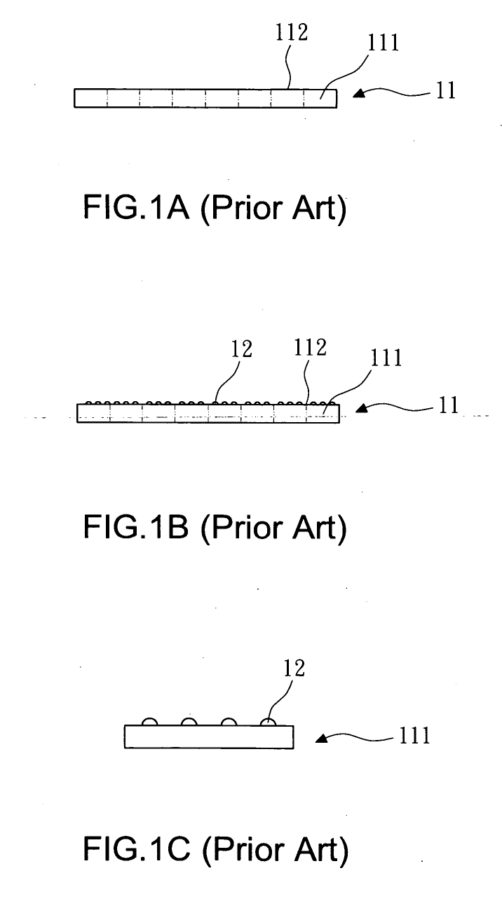

### DETAILED DESCRIPTION OF THE INVENTION

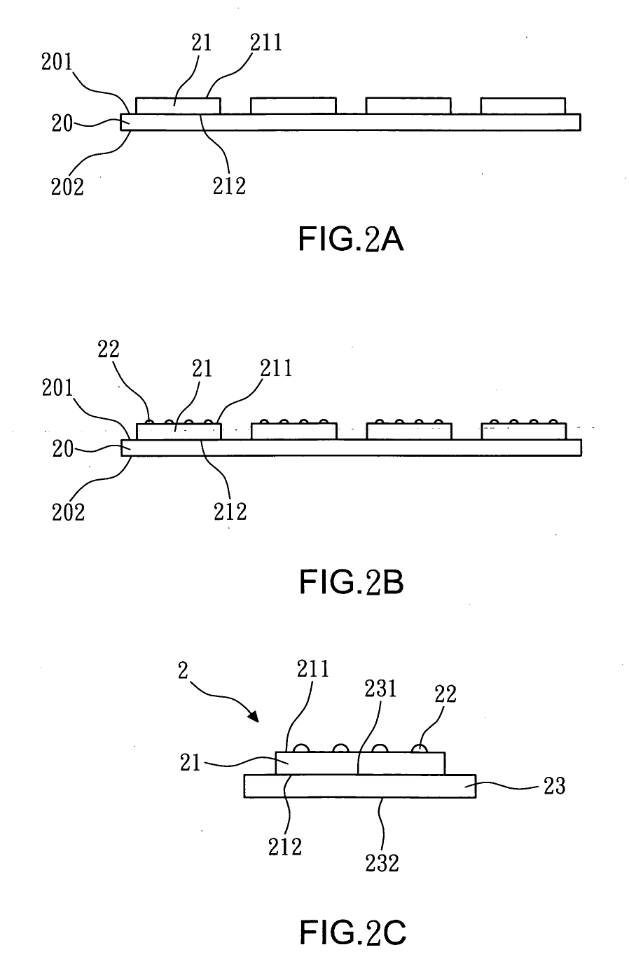

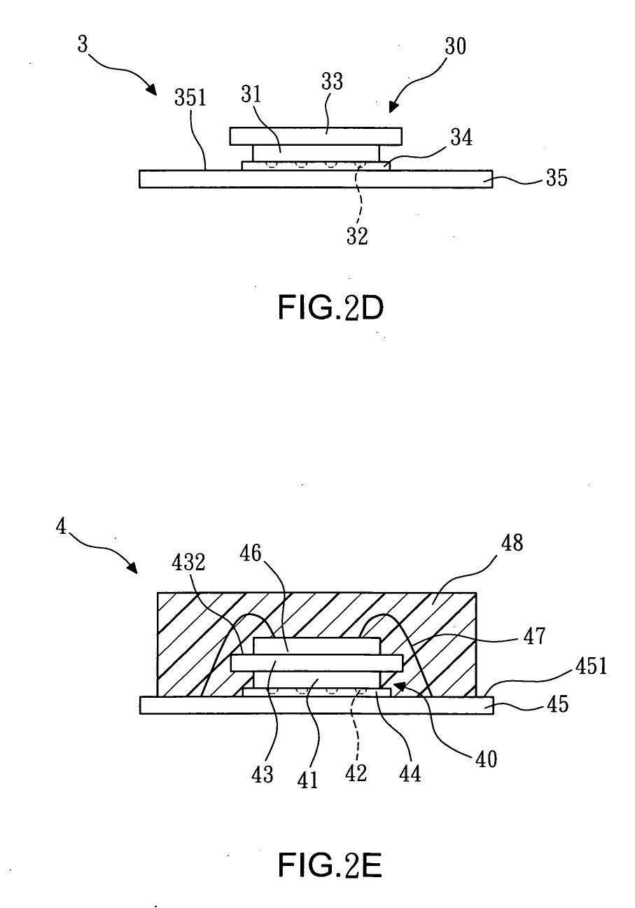

Referring to FIGS. 2A to 2E, they show a method for making a die according to the present invention. Referring to FIG. 2A, firstly, a plate 20 is provided. The plate 20 has a first surface 201 and a second surface 202. In the embodiment, the first surface 201 is a surface with circuits thereon. Alternatively, the second surface 202 can be a surface with circuits thereon. A plurality of first dice 21 are disposed on the first surface 201 of the plate 20. Each die 21 has a first surface 211 and a second surface 212, and the second surface 212 is corresponding to the first surface 211. The dice 21 are disposed in array manner on the first surface 20.1 of the plate 20 by using epoxy.

Referring to FIG. 2B, a plurality of bumps 22 are disposed on the first surface 211 of the dice 22, and preferably, the bumps 22 are gold. Referring to FIG. 2C, the plate 20 is cut to form a plurality of die modules 2. Each die module 2 comprises a plate unit 23, a die 21 and a plurality of bumps 22. The plate unit 23 has a first surface 231. The second surface 212 of the die 21 is mounted on the first surface 231 of the plate unit 23. The bumps 22 are disposed on the first surface 211 of the die 21.

Referring to FIG. 2D, it shows a package with a die module of the present invention. The package 3 comprises a substrate 35, a die module 30 and an adhesive layer 34. The substrate 35 has a first surface 351. The die module 30 is the same as the die module 2 in FIG. 2C. The die module 30 comprises a plate unit 33, a first die 31 and a plurality of bumps 32. The die module 30 is disposed upside down on the first surface 351 of the substrate 35, and the bumps 32 electrically connect to the first surface 351 of the substrate 35 directly. The adhesive layer 34 (e.g., underfill or anisotropic conductive adhesive film, ACF) is used to enhance and is used to protect the connection between the die module 30 and the substrate 35.

Referring to FIG. 2E, it shows a stacked package with a die module according to the present invention. The stacked package 4 comprises a first die module 40, a substrate 45, a second die 46 and encapsulating material 48. The first die module 40 is the same as the die module 30 in FIG. 2D. The first die module 40 comprises a plate unit 43, a first die 41 and a plurality of bumps 42. The first die module 40 is disposed upside down on a first surface 451 of the substrate 45, and the bumps 42 electrically connect to the first surface 451 of the substrate 45 directly. The adhesive layer 44 (e.g., underfill or anisotropic conductive adhesive film, ACF) is used to enhance and is used to protect the connection between the first die module 40 and the substrate 45.

The second die 46 is mounted on a second surface 451 of the plate unit 43 by an adhesive material. The second die 46 electrically connects to the first surface 451 of the substrate 45 by a plurality of wires 47. The encapsulating material 48 is used to encapsulate the first die module 40, the second die 46 and the wires 47 to form the stacked package 4.

Therefore, by utilizing the method of the invention, mounting bumps on a single die becomes easier, so that the shortcomings of the conventional method can be improved, and the time for mounting bumps on a single die can be saved.

While the embodiments of the present invention have been illustrated and described, various modifications and improvements can be made by those skilled in the art. The embodiments of the present invention are therefore described in an illustrative but not restrictive sense. It is intended that the present invention may not be limited to the particular forms as illustrated, and that all modifications that maintain the spirit and scope of the present invention are within the scope as defmed in the appended claims.

What is claimed is:

1. A packaging method for a package with a die module, the packaging method comprising the steps of:
(a) providing a plate, having a first surface and a second surface;
(b) forming a plurality of first dice on the plate, the first dice having a first surface and a second surface;
(c) forming a plurality of bumps on the first surface of the first dice; and
(d) cutting the plate to form a plurality of die modules, each module comprising a plate unit, a first die and a plurality of bumps, the first die disposed on a first surface of the plate unit.

2. The method according to claim 1, wherein the first dice are disposed on the plate by using epoxy in the step (b).

3. The method according to claim 1, wherein the bumps are gold.

4. The method according to claim 1, after step (d), further comprising a step (e): disposing the die module upside down on a first surface of a substrate, wherein the bumps electrically connect to the first surface of the substrate directly.

5. The method according to claim 4, after step (e), further comprising a step (f): disposing a second die on a second surface of the plate unit, and the second die electrically connecting to the first surface of the substrate.

6. The method according to claim 1, wherein the first surface is a surface with circuits thereon.

7. The method according to claim 1, wherein the second surface is a surface with circuits thereon.
